(19) United States
(12) Patent Application Publication
(10) Pub. No.: US 2011/0012255 A1
(43) Pub. Date: Jan. 20, 2011

(54) SEMICONDUCTOR DEVICE

(75) Inventor: Shigeaki SUGANUMA, Nagano (JP)

Correspondence Address: KRATZ, QUINTOS & HANSON, LLP, 1420 K Street, N.W., 4th Floor, WASHINGTON, DC, 20005, US

(73) Assignee: SHINKO ELECTRIC INDUSTRIES CO., LTD., Nagano-shi (JP)

(21) Appl. No.: 12/828,844

(22) Filed: Jul. 1, 2010

(30) Foreign Application Priority Data
Jul. 16, 2009 (JP) 2009-167915

(51) Int. Cl. H01L 23/34

(52) U.S. Cl. 257/712; 257/E23.08

(57) ABSTRACT

A semiconductor device includes a wiring substrate, a first semiconductor chip mounted on the wiring substrate, a second semiconductor chip mounted to the wiring substrate in a lateral direction thereof, a first radiation unit connected to the first semiconductor chip, and arranged to extend from an upper side of the first semiconductor chip to an upper side the second semiconductor chip, and a second radiation unit connected to the second semiconductor chip, and arranged to extend from an lower side of the first radiation unit to an outside thereof in a non-contact state to the first radiation unit.

### CROSS-REFERENCE TO RELATED APPLICATIONS

This application is based on and claims priority of Japanese Patent Application No. 2009-167915 filed on Jul. 16, 2009, the entire contents of which are incorporated herein by reference.

### BACKGROUND OF THE INVENTION

1. Field of the Invention

The present invention relates to a semiconductor device and, more particularly, a semiconductor device having a radiation unit such as a heat spreader, or the like.

2. Description of the Related Art

In the prior art, there is the semiconductor device having a radiation function such as the heat spreader, or the like. In such semiconductor device, the semiconductor chip is mounted on the wiring substrate, and the heat spreader, or the like is connected to the semiconductor chip so as to radiate a heat generated from the semiconductor chip to the outside.

In Patent Literature 1 (Patent Application Publication (KOKAI) Hei 7-202120), the high radiation type memory module in which memory element mounted on the heat radiant substrate is connected electrically to the lead pins is mounted in plural vertically on the surface mounting substrate is disclosed.

As explained in the column of the related art described later, when the CPU chip and the memory chip are mounted on the wiring substrate, the memory chip is arranged in vicinity of the CPU chip so as to ensure a bandwidth between the CPU chip and the memory chip. Then, the common heat spreader is arranged to be connected to the CPU chip and the memory chip.

Because an amount of heat generation of the CPU chip in operation is considerably larger than that of the memory chip, a heat of the CPU chip is conducted to the memory chip via the heat spreader. Therefore, a malfunction of the memory chip is caused due to the heat from the CPU chip. As a result, such a problem exists that sufficient reliability of the semiconductor device cannot be obtained.

### SUMMARY OF THE INVENTION

It is an object of the present invention to provide a semiconductor device capable of radiating sufficiently a heat of a first semiconductor chip and also ensuring reliability of a second semiconductor chip without the influence of a heat from the first semiconductor chip, even when the second semiconductor chip whose amount of heat generation is smaller than the first semiconductor chip is arranged in vicinity of the first semiconductor chip whose amount of heat generation is large.

The present invention is concerned with a semiconductor device, which includes a wiring substrate; a first semiconductor chip mounted on the wiring substrate; a second semiconductor chip mounted to the wiring substrate in a lateral direction of the first semiconductor chip; a first radiation unit connected to the first semiconductor chip, and arranged to extend from an upper side of the first semiconductor chip to an upper side the second semiconductor chip; and a second radiation unit connected to the second semiconductor chip, and arranged to extend from an lower side of the first radiation unit to an outside thereof in a non-contact state to the first radiation unit.

In the semiconductor device of the present invention, the first semiconductor chip (the CPU chip, or the like) and the second semiconductor chip (the memory chip, or the like) are mounted on the wiring substrate side by side in the lateral direction. In the preferred mode, the first semiconductor chip has such a characteristic that an amount of heat generation in operation is larger than that of the second semiconductor chip.

The first radiation unit that is extended from an area over the first semiconductor chip to an area over the second semiconductor chip is connected to the first semiconductor chip. Also, the second radiation unit which is extended in a non-contact state to the first radiation unit from a lower side of the first radiation unit to the outside is connected to the second semiconductor chip.

In the present invention, in order to prevent that the heat generated from the first semiconductor chip is conducted to the second semiconductor chip, the first semiconductor chip is thermally coupled independently to the first radiation unit, and the second semiconductor chip is thermally coupled independently to the second radiation unit which is separated from the first radiation unit.

The space may be formed between the second radiation unit and the first radiation unit over the second semiconductor chip, or the heat insulating material may be formed between them.

In one preferred mode of the present invention, the first radiation unit is formed of the radiation metal member which is made of copper, copper alloy, or the like, and the second radiation unit is formed of the water-cooling jacket or the anisotropic heat conduction material whose heat conductivity in the horizontal direction is higher than the heat conductivity in the vertical direction.

### BRIEF DESCRIPTION OF THE DRAWINGS

FIG. 1 is a sectional view showing a first semiconductor device in the back ground art;

FIG. 2 is a sectional view showing a second semiconductor device in the back ground art;

FIG. 3 is a sectional view showing a semiconductor device according to a first embodiment of the present invention;

FIG. 4 is a perspective plan view showing the semiconductor device in FIG. 3 when viewed from the top;

FIG. 5 is a sectional view showing a semiconductor device according to a first variation of the first embodiment of the present invention;

FIG. 6 is a sectional view showing a semiconductor device according to a second variation of the first embodiment of the present invention;

FIG. 7 is a sectional view showing a semiconductor device according to a third variation of the first embodiment of the present invention;

FIG. 8 is a sectional view showing a semiconductor device according to a second embodiment of the present invention;

FIG. 9 is a sectional view showing a semiconductor device according to a first variation of the second embodiment of the present invention;

FIG. 10 is a sectional view showing a semiconductor device according to a second variation of the second embodiment of the present invention;

FIG. 11 is a sectional view (#1) showing a semiconductor device according to a third embodiment of the present invention;

FIG. 12 is a sectional view (#2) showing the semiconductor device according to the third embodiment of the present invention;

FIG. 13 is a sectional view (#3) showing the semiconductor device according to the third embodiment of the present invention; and

FIG. 14 is a sectional view (#4) showing the semiconductor device according to the third embodiment of the present invention.

### DETAILED DESCRIPTION OF THE PREFERRED EMBODIMENTS

Embodiments of the present invention will be explained with reference to the accompanying drawings hereinafter.

### Back Ground Art

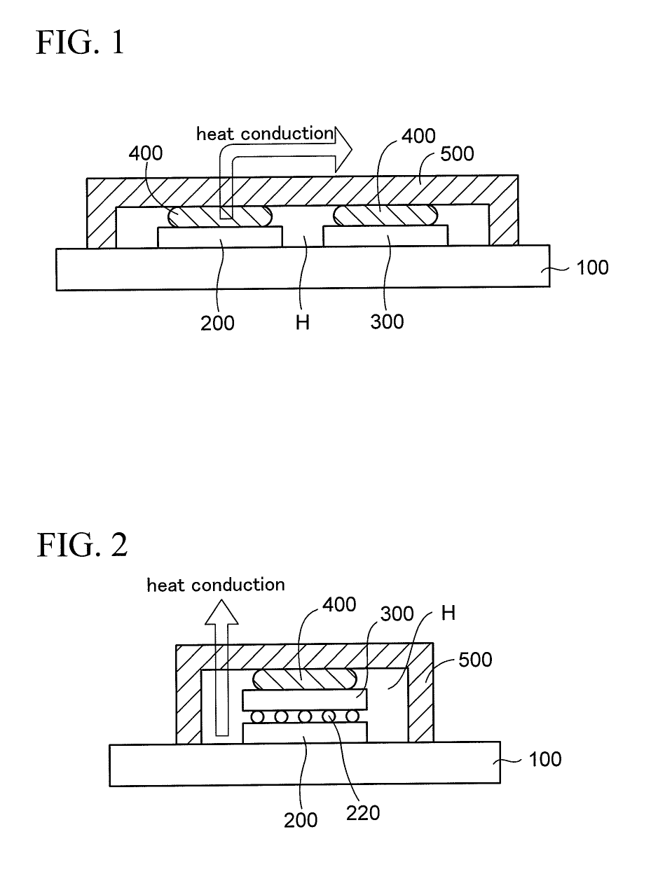

Prior to the explanation of embodiments of the present invention, the problem in the back ground art associated with the present invention is explained. FIG. 1 is a sectional view showing a first semiconductor device in the back ground art, and FIG. 2 is a sectional view showing a second semiconductor device in the back ground art.

As shown in FIG. 1, in the first semiconductor device in the back ground art, a CPU chip 200 and a memory chip 300 are mounted on a wiring substrate 100 side by side in the lateral direction. In order to ensure a bandwidth between the CPU chip 200 and the memory chip 300, the memory chip 300 is arranged in vicinity of the CPU chip 200.

A heat spreader 500 is arranged over the CPU chip 200 and the memory chip 300. A housing portion H is provided under the heat spreader 500, and the CPU chip 200 and the memory chip 300 are housed in the housing portion H. A radiation material 400 made of indium, or the like is provided between upper surfaces of the CPU chip 200 and the memory chip 300 and a lower surface of the heat spreader 500 respectively.

Accordingly, the heat generated from the CPU chip 200 and the memory chip 300 is radiated to the heat spreader 500 side via the radiation material 400 respectively.

The CPU chip 200 has such a characteristic that an amount of heat generation in operation is considerably larger than that of the memory chip 300. Therefore, the heat which is conducted from the CPU chip 200 to the heat spreader 500 via the radiation material 400 is conducted to the heat spreader 500 side on the side of the memory chip 300 whose temperature is low.

As a result, the heat generated from the CPU chip 200 is conducted to the memory chip 300, and in some cases a malfunction of the memory chip 300 is caused due to the heat, so that such a problem exists that reliability of the semiconductor device cannot be sufficiently achieved.

Also, as shown in FIG. 2, in the second semiconductor device in the back ground art, the CPU chip 200 is mounted on the wiring substrate 100. The memory chip 300 is mounted to be stacked on the CPU chip 200 via connection bumps 220.

Then, the heat spreader 500 is arranged over the memory chip 300 and the CPU chip 200 which are stacked. The housing portion H is provided on the lower surface side of the heat spreader 500, and the memory chip 300 and the CPU chip 200 which are stacked are housed in the housing portion H. The radiation material 400 made of indium, or the like is formed between the upper surface of the memory chip 300 and the lower surface of the heat spreader 500.

In the second semiconductor device, the heat generated from the CPU chip 200 is radiated to the heat spreader 500 side via the memory chip 300 and the radiation material 400. As a result, like the above first semiconductor device, the heat generated from the CPU chip 200 is conducted to the memory chip 300, and thus in some cases a malfunction of the memory chip 300 is caused due to the heat, so that such a problem exists that sufficient reliability of the memory chip 300 cannot be obtained.

In this manner, when either the memory chip 300 is arranged in vicinity of the CPU chip 200 or the memory chip 300 is stacked on the CPU chip 200, such a problem exists that sufficiently reliability of the memory chip 300 cannot be obtained due to the influence of heat from the CPU chip 200.

Semiconductor devices of the present embodiments explained hereinafter can solve the foregoing failures.

### First Embodiment

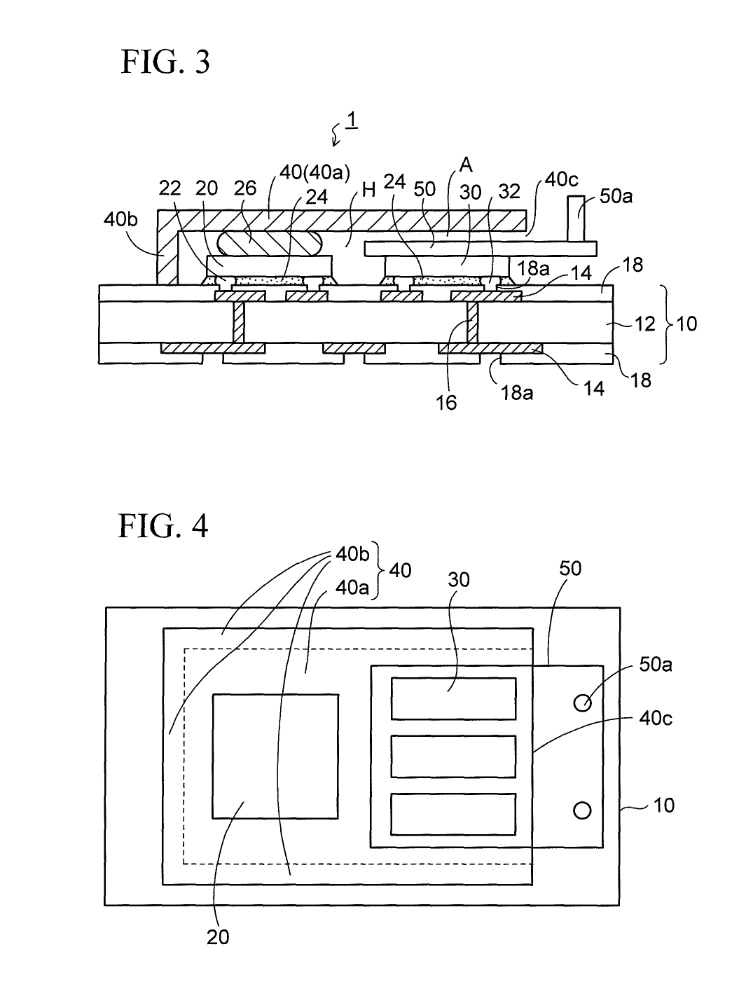

FIG. 3 to FIG. 7 are sectional views (including a plan view) showing a semiconductor device according to a first embodiment of the present invention.

As shown in FIG. 3, in a wiring substrate 10 constituting a semiconductor device 1 of the first embodiment, a wiring layer 14 is formed on both surface side of an insulating substrate 12 respectively. Penetrating electrodes 16 which are formed to penetrate the insulating substrate 12 in the thickness direction are provided to the insulating substrate 12, and the wiring layers 14 on both surface sides are connected mutually via the penetrating electrodes 16. A solder resist 18 in which an opening portions 18a are provided on connection portions of the wiring layers 14 is formed on both surface sides of the insulating substrate 12 respectively.

In addition to the wiring substrate 10 illustrated in FIG. 3, wiring substrates having various structure can be employed.

Connection bumps 22 of a CPU (Central Processing Unit) chip 20 are mounted to be flip-chip connected to the connection portions of the wiring layers 14 on the upper surface side of the wiring substrate 10. The CPU chip 20 is an example of the first semiconductor chip.

Also, connection bumps 32 of a memory chip 30 are mounted to be flip-chip connected to the connection portions of the wiring layers 14 located to a lateral side of the CPU chip 20, and are mounted thereon. The memory chip 30 is an example of the second semiconductor chip.

Also, an underfill resin 24 is filled in a clearance in a lower side of the CPU chip 20 and the memory chip 30 respectively.

In this case, a GPU (graphics processor unit) chip may be mounted instead of the CPU chip 20, or a semiconductor chip in which both functions of the CPU and the GPU are integrated may be mounted.

Also, as the memory chip 30, there are DRAM chip, SRAM chip, flash memory chip, FeRAM (ferroelectric memory) chip, and the like.

The CPU chip 20 (first semiconductor chip) has such a characteristic that an amount of heat generation in operation is considerably larger than that of the memory chip 30 (second semiconductor chip).

It is required in the semiconductor device that a bandwidth between the CPU chip 20 and the memory chip 30 should be ensured. In order to ensure the bandwidth, such a structure is preferable that the memory chip 30 is located closely to the CPU chip 20. Therefore, the memory chip 30 is arranged in vicinity of the CPU chip 20, and a distance between the CPU chip 20 and the memory chip 30 is set to 2 to 3 mm, for example.

Here, the “bandwidth” denotes a width between a lower limit and an upper limit of the frequency used in the data transmission. When the bandwidth is wide, more data can be transmitted in a predetermined time, and thus the high-performance semiconductor device can be constructed.

A radiation metal member 40 (first radiation unit) made of copper, copper alloy, or the like is arranged over the CPU chip 20 and the memory chip 30. The radiation metal member 40 is also called the heat spreader.

By referring to a plan view of FIG. 4 together with FIG. 3, the radiation metal member 40 is constructed by a top plate portion 40a having a square-like shape and three side portions 40b that are protruded downward from the peripheral portion of the top plate portion 40a respectively. No side portion is provided to one side of the radiation metal member 40 on the memory chip 30 side, and an opening portion 40c opened to the outside is formed. In the plan view of FIG. 4, respective elements are depicted in a see-through fashion.

In this manner, three side portions 40b of the radiation metal member 40 are joined to the wiring substrate 10, thus the housing portion H is constructed to the lower surface side of the radiation metal member 40. Then, the CPU chip 20 and the memory chip 30 are housed in the housing portion H of the radiation metal member 40. Also, a radiation material 26 made of indium, or the like is provided between the upper surface of the CPU chip and the lower surface of the radiation metal member 40. Accordingly, the radiation metal member is thermally coupled to the CPU chip 20 via the radiation material 26.

In this way, the heat generated from the CPU chip 20 is radiated to the radiation metal member 40 via the radiation material 26.

Also, a water-cooling jacket 50 (second radiation unit) which is separated from the radiation metal member 40 is connected to the upper surface of the memory chip 30. The water-cooling jacket 50 is arranged to extend from the lower side of the radiation metal member 40 to the outside through the opening portion 40c of the radiation metal member 40.

The water-cooling jacket 50 is kept in a non-contact state to the radiation metal member 40 in the area where the radiation metal member 40 overlaps with the water-cooling jacket 50. In the example of FIG. 3, a space A (clearance) is formed between the lower surface of the radiation metal member 40 and the upper surface of the water-cooling jacket 50.

In the water-cooling jacket 50, fine slits are formed in a jacket made of copper, and a cooling liquid is circulated in the fine slits, thereby the subject can be cooled.

A cooling system is constructed by a pump (not shown) for circulating the cooling liquid, a radiator (not shown) for radiating the heat to the outside, pipes (not shown) for connecting them to flow the cooling liquid, etc., in addition to the water-cooling jacket 50. A pipe insertion port 50a to which the pipe for supplying the cooling liquid is connected is provided upright to the outer end portion of the water-cooling jacket 50 in FIG. 3.

In this manner, the heat generated from the memory chip 30 is radiated to the outside by the water-cooling jacket 50.

As explained in the above back ground art, the CPU chip 20 has such a characteristic that an amount of heat generation in operation is considerably larger than that of the memory chip 30. Therefore, such an event must be prevented that the heat generated from the CPU chip 20 is conducted to the memory chip 30.

For this purpose, in the present embodiment, the CPU chip 20 is thermally coupled independently to the radiation metal member 40, and the memory chip 30 is thermally coupled independently to the water-cooling jacket 50 which is separated from the radiation metal member 40. That is, the radiation paths of the CPU chip 20 and the memory chip 30 are separated mutually and heat-insulation is done such that a thermal interference is not caused between the CPU chip 20 and the memory chip 30.

In the semiconductor device 1 of the present embodiment, the heat generated from the CPU chip 20 is radiated to the radiation metal member 40 via the radiation material 26 on the CPU chip 20. At this time, the water-cooling jacket 50 whose cooling capability is high is arranged on the memory chip 30. Therefore, even when the heat is conducted from the radiation metal member 40 over the memory chip 30 to the memory chip 30 side via the space A, a heat conduction can be shut off by the water-cooling jacket 50.

As a result, it is not feared that the memory chip 30 is influenced by the heat from the CPU chip 20, so that such a situation can be avoided that a malfunction of the memory chip 30 is caused, and thus reliability of the semiconductor device 1 can be improved.

Accordingly, the memory chip 30 can be arranged in vicinity of the CPU chip 20, and also the bandwidth between the CPU chip 20 and the memory chip 30 can be ensured.

The present embodiment can be applied to various semiconductor chips whose amount of heat generation in operation is different respectively, other than the combination of the CPU chip 20 and the memory chip 30. In this case, the semiconductor chip whose amount of heat generation in operation is large may be connected to the radiation metal member 40, and the semiconductor chip whose amount of heat generation in operation is small may be connected to the water-cooling jacket 50.

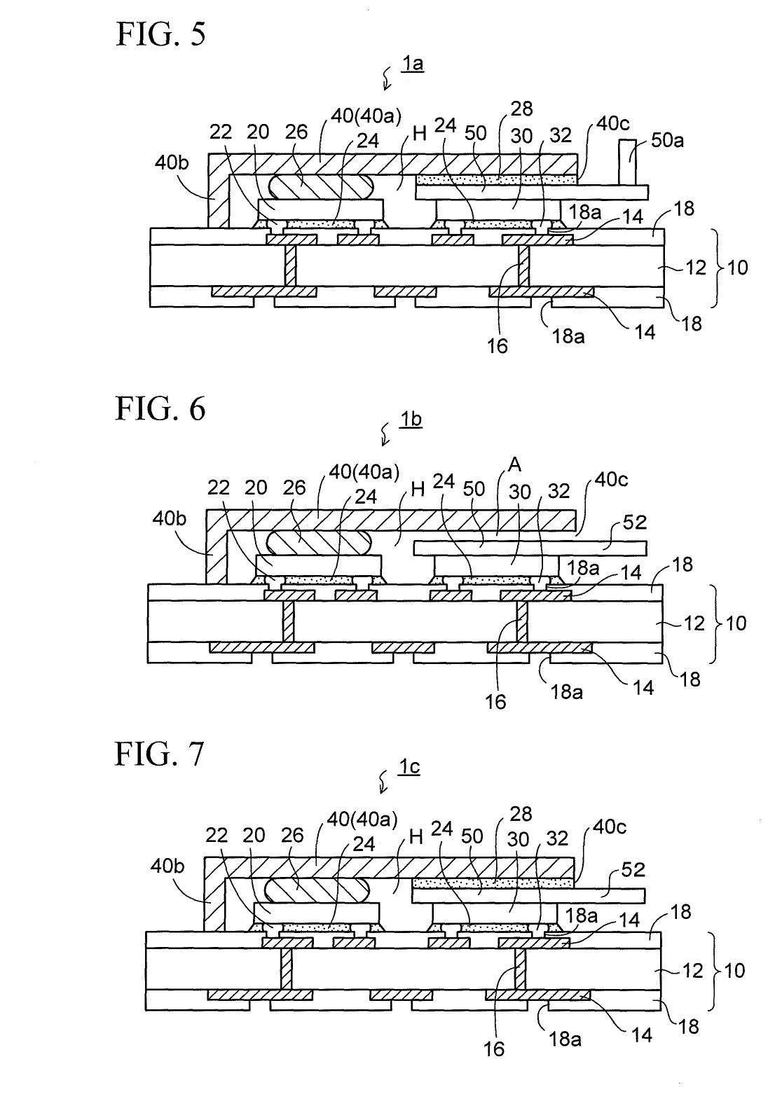

In FIG. 5, a semiconductor device la according to a first variation of the first embodiment of the present invention is shown. In above mentioned FIG. 3, the space A is formed between the radiation metal member 40 and the water-cooling jacket 50. In this case, as shown in FIG. 5, a heat insulating material 28 may be provided between the radiation metal member 40 and the water- cooling jacket 50. As the heat insulating material 28, preferably, a resin such as a sponge-like urethane resin, or the like, which contains bubbles therein, is employed.

By providing the heat insulating material 28 between the radiation metal member 40 and the water-cooling jacket 50, a heat conduction from the radiation metal member 40 to the memory chip 30 side can be suppressed rather than the case where the space A is formed.

Also, in FIG. 6, a semiconductor device lb according to a second variation of the first embodiment of the present invention is shown. As shown in FIG. 6, in above mentioned FIG. 3, a radiation metal member 52 (second radiation unit) identical to the radiation metal member 40 may be arranged on the memory chip 30, instead of the water-cooling jacket 50.

The radiation metal member 52 is connected to the memory chip 30 via radiation material such as indium, or the like (not shown). In FIG. 6, the space A (clearance) is provided between the radiation metal member 40 connected to the CPU chip 20 and the radiation metal member 52 connected to the memory chip 30.

Also, in FIG. 7, a semiconductor device 1c according to a third variation of the first embodiment of the present invention is shown. As shown in FIG. 7, in the semiconductor device 1b according to the second variation in FIG. 6, the heat insulating material 28 may be provided between the radiation metal member 40 connected to the CPU chip 20 and the radiation metal member 52 connected to the memory chip 30.

Here, in the semiconductor devices 1b, 1c according to the second and third variations in FIG. 6 and FIG. 7, a cooling mechanism such as a radiating fin, a water-cooling portion, or the like may be provided on the outer end portion of the radiation metal member 52 connected to the memory chip 30.

In FIG. 5 to FIG. 7, remaining elements are similar to those in FIG. 3 and therefore their explanation will be omitted herein. In the semiconductor devices 1a, 1b, 1c according to the first to third variations, the advantages similar to those of the semiconductor device 1 in FIG. 3 can be achieved.

### Second Embodiment

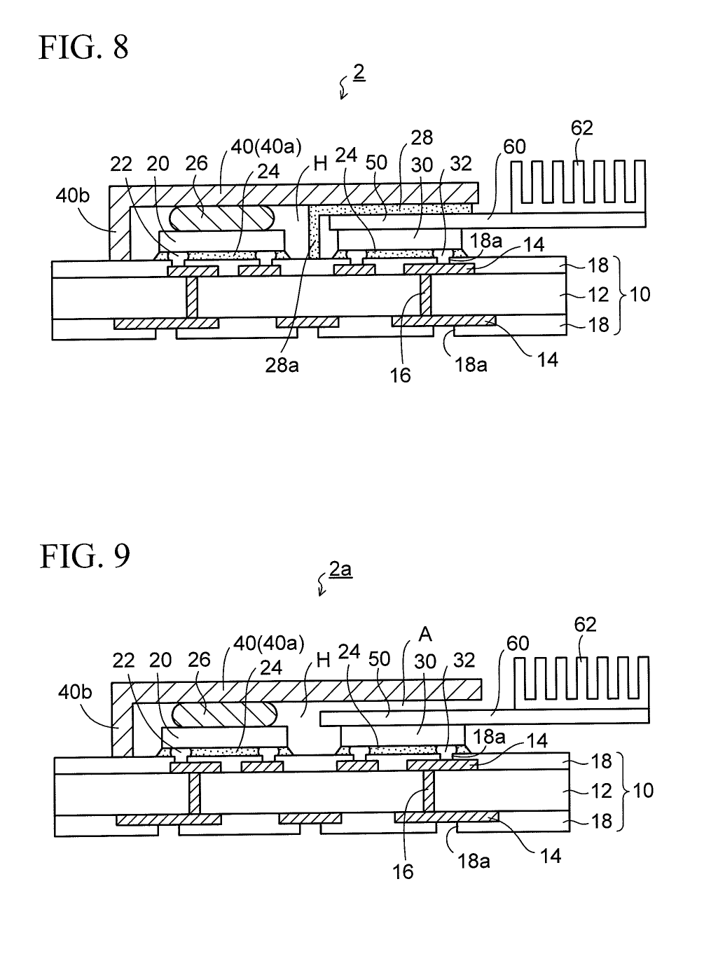

FIG. 8 and FIG. 9 are sectional views showing a semiconductor device according to a second embodiment of the present invention. A feature of the second embodiment resides in that a heat conduction generated from the CPU chip to the memory chip is prevented by connecting an anisotropic heat conduction material to the memory chip.

As shown in FIG. 8, in a semiconductor device 2 of the second embodiment, in place of the water-cooling jacket 50 of the semiconductor device 1 in FIG. 3 of the above mentioned first embodiment, an anisotropic heat conduction material 60 (second radiation unit) is arranged to be connected to the upper surface of the memory chip 30. The anisotropic heat conduction material 60 has an anisotropy of heat conductivity in the horizontal direction (planar direction) and the vertical direction (thickness direction), and has such a characteristic that a heat conductivity in the horizontal direction is higher that a heat conductivity in the vertical direction.

That is, the heat generated from the memory chip 30 to the anisotropic heat conduction material 60 is radiated mainly through the heat transportation path in the horizontal direction. The anisotropic heat conduction material 60 is formed of a flexible graphite sheet, or the like.

A radiating fin 62 is provided to the outer side end portion of the anisotropic heat conduction material 60. The heat which is conducted through the anisotropic heat conduction material 60 is radiated to the outside from the radiating fin 62. A cooling function such as a water-cooling portion, or the like may be provided instead of the radiating fin 62.

Also, in the area where the radiation metal member 40 overlaps with the anisotropic heat conduction material 60, the heat insulating material 28 is provided between the lower surface of the radiation metal member 40 and the upper surface of the anisotropic heat conduction material 60. The heat insulating material 28 is formed to extend from the left end portion of the anisotropic heat conduction material 60 to the CPU chip 20 side, and has a wall portion 28a which is provided upright between the radiation metal member 40 and the solder resist 18 of the wiring substrate 10 such that wall portion 28a partitions the CPU chip 20 and the memory chip 30.

In FIG. 8, remaining elements of the second embodiment are similar to those of the semiconductor device 1 of the above first embodiment shown in FIG. 3. Therefore, their explanation will be omitted herein by affixing the same reference symbols to them.

In the second embodiment 2 of the second embodiment, the heat generated from the CPU chip 20 is radiated to the radiation metal member 40 via the radiation material 26 on the CPU chip 20. At this time, the anisotropic heat conduction material 60 and the heat insulating material 28 are arranged on the memory chip 30. Therefore, the heat transferred from the radiation metal member 40 over the memory chip 30 is shut off by the heat insulating material 28.

In addition, even when the heat cannot be perfectly insulated with the heat insulating material 28, because the anisotropic heat conduction material 60 in which the heat is different to conducted in the thickness direction is arranged on the memory chip 30, such a situation is prevented that the heat generated from the CPU chip 20 is conducted to the memory chip 30.

Also, the wall portion 28a of the heat insulating material 28 is provided between the CPU chip 20 and the memory chip 30. Therefore, the heat which is conducted directly from the CPU chip 20 to the memory chip 30 side in the lateral direction can be shut off by the wall portion 28a.

In FIG. 5 and FIG. 7 of the above mentioned first embodiment, the heat insulating material 28 may be extended as shown in FIG. 8 such that the CPU chip 20 and the memory chip 30 are partitioned with the wall portion 28a of the heat insulating material 28.

Accordingly, it is not feared that the memory chip 30 is influenced by the heat generated from the CPU chip 20. Therefore, a malfunction of the memory chip 30 can be avoided, and reliability of the semiconductor device 2 can be improved.

As a result, the memory chip 30 can be arranged in vicinity of the CPU chip 20, and the bandwidth between the CPU chip 20 and the memory chip 30 can be ensured.

In FIG. 8, the heat insulating material 28 is provided between the radiation metal member 40 and the anisotropic heat conduction material 60. In this case, like a semiconductor device 2a according to a first variation of the second embodiment shown in FIG. 9, the space A (clearance) may be provided between the radiation metal member 40 and the anisotropic heat conduction material 60.

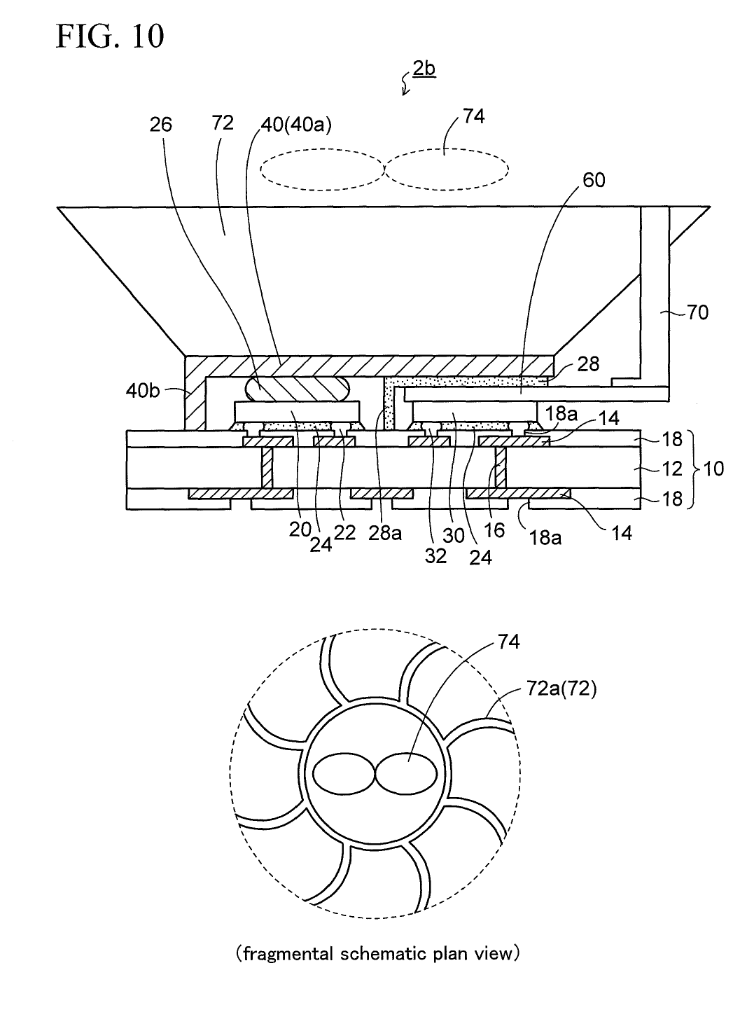

In FIG. 10, a semiconductor device 2b according to a second variation of the second embodiment is shown. As shown in FIG. 10, in the semiconductor device 2b according to the second variation, a heat pipe 70 is provided upright to the outer end portion of the anisotropic heat conduction material 60, instead of the radiating fin 62 in the above semiconductor device 2 in FIG. 8.

Further, as a fragmental schematic plan view in FIG. 10 is referred in addition, a heat sink 72 having radiating fins 72a and an air-cooling fan 74 are provided on the radiation metal member 40, and the heat pipe 70 is connected to the top portion of the heat sink 72. In the heat pipe 70, a refrigerant is set in the metal pipe, and an exhaust heat is done by utilizing a latent heat in evaporation and condensation of the refrigerant. A size of the air-cooling fan 74 may be set to correspond to an outer shape of the heat sink 72.

Also, the heat generated from the CPU chip 20 is conducted to the heat sink 72 via the radiation material 26 and the radiation metal member 40, and is radiated to the outside by the air-cooling fan 74. Also, the heat conducted to the anisotropic heat conduction material 60 connected to the memory chip 30 is carried to the upper portion, a temperature of which is low, of the heat sink 72 through the heat pipe 70, and is radiated to the outside by the air-cooling fan 74.

By employing the above heat transportation path, even when the CPU chip 20 whose amount of heat generation is large is mounted, the heat can be radiated effectively to the outside, not to cause the heat to conduct from the CPU chip 20 to the memory chip 30.

### Third Embodiment

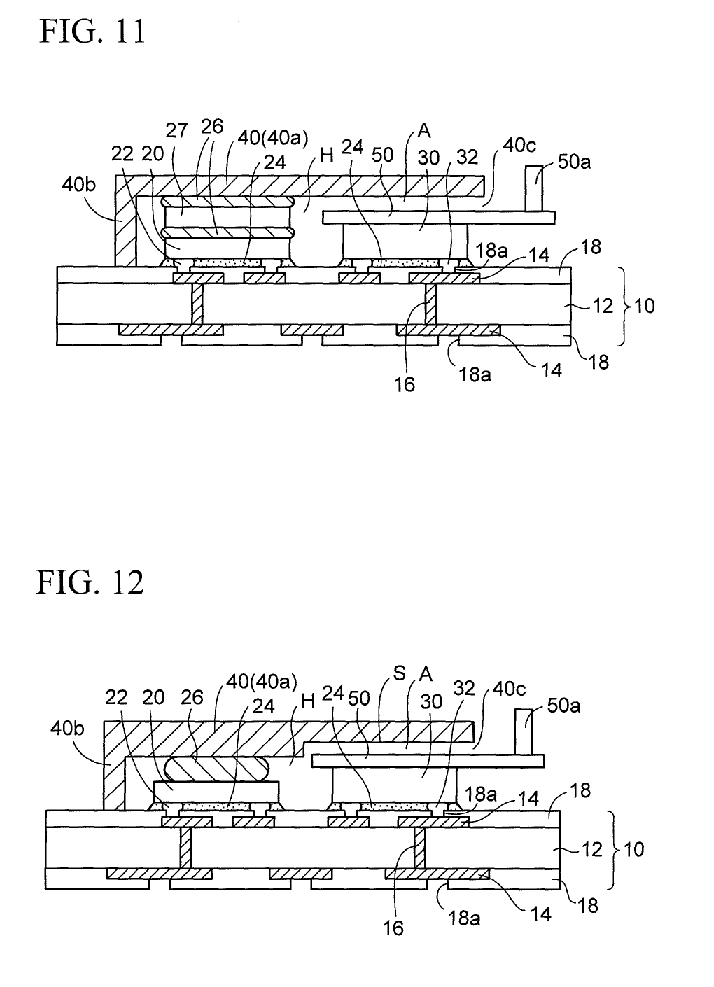

FIG. 11 to FIG. 14 are sectional views showing a semiconductor device according to a third embodiment of the present invention.

In the semiconductor device 1 in FIG. 3 or the like of the above mentioned first embodiment, in the case that the height of the memory chip 30 is higher than the height of the CPU chip 20, such a case is assumed that the space A cannot be ensured between the radiation metal member 40 and the water-cooling jacket 50.

Also, in the case that the radiation material 26 formed on the CPU chip 20 is very thin, the space A cannot be ensured between the radiation metal member 40 and the water-cooling jacket 50.

As shown in FIG. 11, in the case that the thickness of the memory chip 30 is set thicker than the thickness of the CPU chip 20, a radiation member 27 may be provided on the CPU chip 20 via the radiation material 26 to ensure a desired height. Then, the radiation member 27 is connected to the radiation metal member 40 via the radiation material 26. The material other than a metal may be employed as the radiation member 27, and it is desired that the material having high radiation performance should be employed.

Also, as shown in FIG. 12, a level difference S may be provided to a part of the radiation metal member 40 located over the memory chip 30. Thus, a thickness of the radiation metal member 40 located over the memory chip 30 may be made thin partially.

By doing this, even when the height of the memory chip 30 is higher than the height of the CPU chip 20, the space A can be ensured between the radiation metal member 40 and the water-cooling jacket 50.

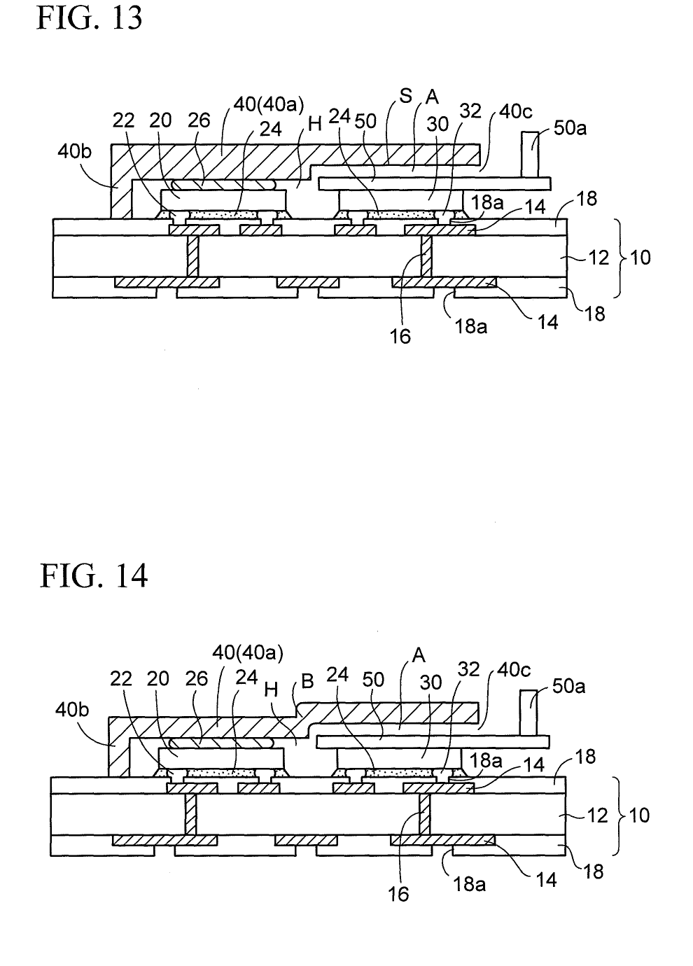

Also, as shown in FIG. 13, in the case that the radiation material 26 formed on the CPU chip 20 is very thin, the level difference S may be provided to a part of the radiation metal member 40 located over the memory chip 30, like FIG. 12. Thus, a thickness of the radiation metal member 40 located over the memory chip 30 may also be made thin partially.

Further, as shown in FIG. 14, in the case that the radiation material 26 formed on the CPU chip 20 is very thin, a bent portion B being bent upwardly may be provided to a part of the radiation metal member 40 between the CPU chip 20 and the memory chip 30. Thus, a height of the radiation metal member 40 located over the memory chip 30 may be made high partially.

By doing this, even when the radiation material 26 formed on the CPU chip 20 is very thin, the space A can be ensured between the radiation metal member 40 and the water-cooling jacket 50.

The structure in the third embodiment is applicable to the semiconductor device in the second embodiment.

What is claimed is:

1. A semiconductor device, comprising:
a wiring substrate;
a first semiconductor chip mounted on the wiring substrate;
a second semiconductor chip mounted on the wiring substrate in a lateral direction of the first semiconductor chip;
a first radiation unit connected to the first semiconductor chip, and arranged to extend from an upper side of the first semiconductor chip to an upper side the second semiconductor chip; and
a second radiation unit connected to the second semiconductor chip, and arranged to extend from an lower side of the first radiation unit to an outside thereof in a non-contact state to the first radiation unit.

2. A semiconductor device according to claim 1, wherein the first radiation unit is formed of a metal member connected to an upper surface of the first semiconductor chip via a radiation material, and the second radiation unit is formed of a water-cooling jacket.

3. A semiconductor device according to claim 1, wherein the first radiation unit is formed of a metal member connected to an upper surface of the first semiconductor chip via a radiation material, and the second radiation unit is formed of an anisotropic heat conduction material whose heat conductivity in a horizontal direction is higher than the heat conductivity in a vertical direction.

4. A semiconductor device according to claim 1, wherein a space is formed between the first radiation unit and the second radiation unit in an area where the first radiation unit overlaps with the second radiation unit.

5. A semiconductor device according to claim 1, wherein a heat insulating material is provided between the first radiation unit and the second radiation unit in an area where the first radiation unit overlaps with the second radiation unit.

6. A semiconductor device according to claim 5, wherein the heat insulating material has a wall portion which is provided upright such that the wall portion partitions the first semiconductor chip and the second semiconductor chip.

7. A semiconductor device according to claim 3, wherein the anisotropic heat conduction material is formed of a graphite sheet.

8. A semiconductor device according to claim 1, wherein the first semiconductor chip is a semiconductor chip which has at least one function of CPU and GPU, and the second semiconductor chip is a memory chip.
